(19) United States
(12) Patent Application Publication
(10) Pub. No.: US 2022/0178011 A1
(43) Pub. Date: Jun. 9, 2022

(54) METHOD FOR COATING A MECHANICALLY HIGHLY LOADED SURFACE OF A COMPONENT, AND COATED COMPONENT ITSELF

(71) Applicant: Robert Bosch GmbH, Stuttgart (DE)

(72) Inventor: Bernhard Mandl, Linz (AT)

(21) Appl. No.: 17/604,817

(22) PCT Filed: Mar. 24, 2020
(86) PCT No.: PCT/EP2020/058133

§ 371 Date: Oct. 19, 2021

(30) Foreign Application Priority Data
May 3, 2019 (DE) 10 2019 206 420.5

(51) Int. Cl. C23C 10/32; C23C 16/50; C23C 16/26; F02M 59/46; F02M 61/10; C23C 28/00

(52) U.S. Cl. CPC C23C 10/32; C23C 16/50; C23C 16/26; F02M 2200/9053; F02M 61/10; C23C 28/343; F02M 2200/9038; F02M 59/46

(57) ABSTRACT

The invention relates to a method for coating a mechanically highly loaded surface (2) of a component (1) consisting of a hardened steel with a nitrogen and/or carbon component with an adherent or functional coating (4) for surface treatment, wherein a metallic binding material (5) is introduced into the surface (2) prior to the application of the adherent or functional coating (4) to create a graduated diffusion barrier zone (3) conforming to the surface with a proportion of metal nitride and/or metal carbide increasing towards the surface (2).

### BACKGROUND OF THE INVENTION

The present invention relates to a process for coating a mechanically highly stressed surface of a component consisting of a hardened steel having a proportion of nitrogen and/or carbon with a bonding layer and/or functional layer for surface upgrading. Furthermore, the invention also relates to a component itself which has been coated by means of this process and can be, for example, a high-pressure valve component, a fuel pump component or the like.

The field of application of the invention extends from predominantly tribologically highly stressed components, preferably in motor vehicle engineering. Functional layers for surface upgrading serve primarily for protection against wear and represent a widespread means of increasing durability. If protection of the uncoated counterbody is also desired in addition to protection against wear of the coated component, hard material layers and DLC coating (diamond-like carbon) have become established. Hard material layers can, for example, consist of metal nitrides or metal carbides. Particularly in automobile engineering, components such as high-pressure components are highly stressed locally with adherence to very small dimensional tolerances. Thus, for example, high-pressure valve components or high-pressure pump components in fuel injection systems are protected against wear by means of DLC layers. In common rail systems for directly injected diesel engines, the nozzle needles of the fuel injectors are also protected by means of DLC layers at the sealing seat and, depending on the application, also in the region of the needle guide. At the sealing seat, the layer system must, due to superimposition of oscillatory movements of the fuel system, withstand intensive multiple stresses caused by high contact pressures, unfavorable geometries, a high number of switching cycles as a result of multiple injections and unfavorable ambient conditions due to temperatures of the combustion chamber, aggressive exhaust gases and also fuel influences.

DE 10 2005 037 549 A1 discloses a coating for mechanically highly stressed components of the type which is of interest here; this coating consists of a first hard wear protection layer as functional layer and a flexible fitting layer arranged thereon. Here, the fitting layer is less hard and more flexible than the underlying wear protection layer. As a result, the flexible fitting layer wears away more quickly during operation and allows more uniform and earlier sustaining of seat geometries in the case of valves and the like. In particular, manufacturing tolerances or different running-in conditions can be compensated for thereby and a high degree of wear protection can be achieved at the same time. The wear protection layer consists of DLC having a thickness of up to 3 μm and a hardness of up to 20-70 GPa, while the flexible fitting layer consists of DLC having a thickness of up to 5 μm and an accordingly lower hardness of up to 10-30 GPa.

DE 102 13 661 A1 discloses a process for producing a coating on a metallic component. Here, the component is pickled on the surface by means of an inert gas in a plasma and then coated by means of a plasma-enhanced CVD (chemical vapor deposition) process. An oxygen-containing gas is at least partly added to the inert gas. Particularly good layer adhesion is achieved by this means.

The functional layer of a component of the type of interest here therefore has to have reliable layer bonding of the coating applied to the component surface. Apart from the actual functional layer to obtain the desired surface upgrading, an additional bonding layer can for this purpose be applied directly to the component surface, and the functional layer is then in turn applied on top of this.

If the component to be coated consists of a hardened steel which thus normally has proportions of nitrogen and/or carbon, it is important to avoid penetration of nitrogen and/or carbon from the hardened steel into the bonding layer or functional layer in order to suppress undesirable conversion of material into metal nitrides or metal carbides in the region of the coating, which can lead to an increase in the surface stress and to a detachment effect of the coating.

### SUMMARY OF THE INVENTION

It is therefore an object of the present invention to provide a process for coating the surface of a component of the type in question, which process makes it possible to apply a durable bonding layer or functional layer with a minimal manufacturing effort.

The invention encompasses the process engineering teaching that a metallic binder material is firstly introduced into the surface of the component consisting of a hardened steel having a proportion of nitrogen and/or carbon in order to create a gradated diffusion barrier zone conforming to the surface and having a proportion of metal nitride and/or metal carbide which increases in the direction of the surface before application of the bonding layer or functional layer.

In other words, a diffusion barrier zone conforming to the surface is produced in this way in order to impede or prevent penetration of nitrogen and/or carbon from the hardened steel into the coating, i.e. the bonding layer or functional layer. For the present purposes, a zone conforming to the surface means that this diffusion barrier zone does not represent a coating on the surface but instead penetrates into the surface of the component and thus follows the surface topography of the component and thus does not impair this topography. In this way, existing fissures in the surface can be retained so that the bonding layer or functional layer applied thereto adheres better. The gradated diffusion barrier zone is also characterized by a concentration gradient along the zone thickness which is formed by the proportion of metal nitride and/or metal carbide increasing in the direction of the surface, which increasing proportion is formed by the nitrogen and/or carbon diffusing out of the hardened steel. This produces an effective diffusion barrier in the direction of the component surface, so that further nitrogen and/or carbon can no longer get into the region of the bonding layer or functional layer or the diffusion of nitrogen or carbon into the bonding layer or functional layer through the diffusion barrier is significantly reduced.

The introduction of the metallic binder material is preferably carried out by implantation or inward diffusion thereof. Implantation as is known per se involves external acceleration of the binder material by means of an electromagnetic field, so that the binder material is shot into the component surface. Inward diffusion, which is likewise known per se, is a thermal process by means of which the binder material applied to the surface is heated for a sufficient time to such a temperature that incorporation into the surface region of the component occurs and likewise forms the desired gradated diffusion barrier zone conforming to the surface. The introduction of the metallic binder material is in the case of inward diffusion preferably carried out at a process temperature of from 200 to 500° C. Implantation or inward diffusion of the metallic binder material produces layer thicknesses having a penetration depth T of preferably 200 nm, very particularly preferably up to 100 nm. Here, a penetration depth T of up to 100 nm is sufficient to achieve the desired barrier effect. A penetration depth T of more than 200 nm does not lead to any significant improvements in the barrier effect.

The metallic binder material for producing the diffusion barrier zone is selected from a binder metal group comprising chromium, manganese, molybdenum, tungsten and the like. These metals are particularly suitable for binding the nitrogen and/or carbon diffusing out of the hardened steel as nitrides or carbides in order to form the diffusion barrier zone.

The bonding or functional layer which is then to be applied can consist of various materials. An adhesion-promoting bonding layer can preferably be in the form of a chromium or titanium layer which together with a hard material layer as functional layer provides surface upgrading. The hard material layer is preferably composed of DLC or CrN, TiN, AlₓCr_{y}Ti_{z}N. This layer structure produces the desired highly stressable component surfaces.

Tribologically highly stressed components, in particular, of high-pressure valves or high-pressure pumps can be equipped therewith, for example control valve components, reciprocating pistons or nozzle needles and also countercomponents thereof.

### BRIEF DESCRIPTION OF THE DRAWINGS

Further measures for improving the invention will be described in more detail below together with the description of a preferred working example with the aid of the figures. The figures show:

FIG. 1 a schematic longitudinal section through a coating on the surface of a component with diffusion barrier zone, and

FIG. 2 a schematic depiction of the sequence of steps for obtaining a coating as per FIG. 1.

### DETAILED DESCRIPTION

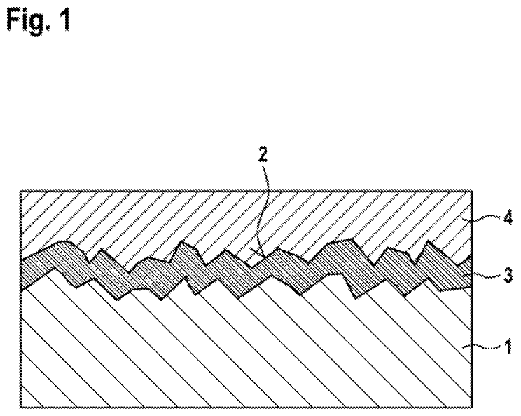

In FIG. 1, a component 1 which is depicted here in a sectional view consists, in a region close to the surface, of a hardened steel having a proportion of nitrogen and carbon. The surface 2 of the component 1 has a fissured surface topology corresponding to the metal microstructure, which shows up here on the microscopic scale. A gradated diffusion barrier zone conforming to the corresponding surface is introduced in such a way that there is a proportion of metal nitride and metal carbide which increases in the direction of the surface 2 and displays a barrier action against further nitrogen and carbon being able to escape to the outside from the hardened steel.

A bonding or functional layer 4 has been applied by means of a plasma-enhanced CVD process to the surface 2 which has been modified in this way. The bonding or functional layer 4 is in this working example configured as a hard material layer consisting of DLC.

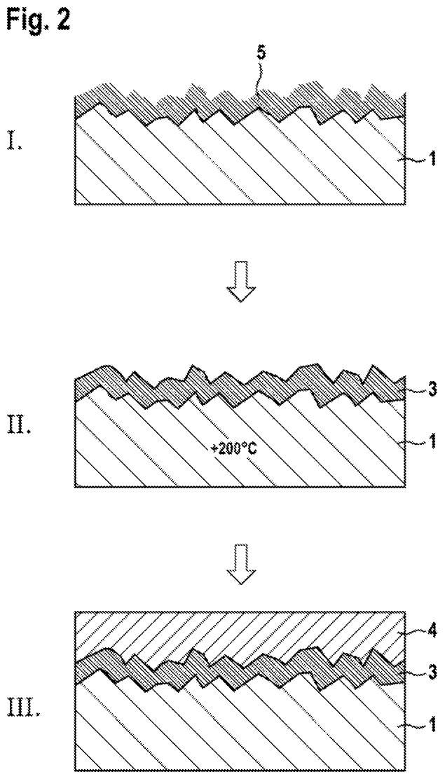

In FIG. 2, a metallic binder material 5 is first applied for coating the surface 2 of a component 1 which consists of a nitrided or carburized chromium-nickel steel as hardened steel alloy. The metallic binder material 5 here is a chromium powder. As a result of the component 1 being heated together with the applied metallic binder material 5 to a temperature of about 200° C., the metallic binder material 5 penetrates into the component 1 over the surface 2, so that a gradated diffusion barrier zone 3 which has an increasing proportion of chromium-based nitride and chromium-based carbide in the direction of the surface 2 is formed in the component 1. Here, the gradated diffusion barrier zone 3 created in this way conforms to the surface.

The bonding or functional layer 4, which serves for the final surface upgrading in order to increase the mechanical stressability of the component 1, is subsequently applied to the surface 2 of the component 1.

The invention is not restricted to the above-described preferred working example. Rather, modifications of this are also conceivable, and these are also encompassed by the scope of protection of the claims below. Thus, it is also possible, for example, firstly to apply an intermediate bonding layer instead of a final functional layer to the component surface, with this intermediate bonding layer subsequently being provided with the functional layer. This layer structure leads, depending on the combination of materials, to a further-improved layer adhesion.

1. A process for coating a mechanically highly stressed surface (2) of a component (1) comprising a hardened steel having a proportion of nitrogen and/or carbon with a bonding layer or functional layer (4) for surface upgrading, characterized in that a metallic binder material (5) is introduced into the surface (2) in order to create a gradated diffusion barrier zone (3) which conforms to the surface and has a proportion of metal nitride and/or metal carbide which increases in the direction of the surface (2) before application of the bonding layer or functional layer (4).

2. The process as claimed in claim 1, characterized in that the introduction of the metallic binder material (5) is carried out by implantation or inward diffusion.

3. The process as claimed in claim 2, characterized in that the introduction of the metallic binder material (5) is in the case of inward diffusion carried out at a process temperature of from 200 to 500° C.

4. The process as claimed in claim 1, characterized in that the introduction of the metallic binder material (5) is carried out with a penetration depth (T) of up to 200 nanometers.

5. A component which has been coated by the process as claimed in claim 1, characterized in that the metallic binder material (5) for producing the diffusion barrier zone (3) is selected from a binder metal group comprising chromium, manganese, molybdenum, tungsten.

6. The component as claimed in claim 5, characterized in that the bonding layer or functional layer (4) is configured as a chromium alloy or titanium alloy layer for promoting adhesion or a hard material layer for surface upgrading.

7. The component as claimed in claim 5, characterized in that the bonding layer or functional layer (4) is configured as a hard material layer comprising diamond-like carbon (DLC).

8. The component as claimed in claim 5, characterized in that the component (1) comprises a nitrided or carburized chromium-nickel steel as hardened steel alloy.

9. A high-pressure valve or high-pressure pump of a fuel injection system of a motor vehicle, which is equipped with a component (1) as claimed in claim 5.

10. The high-pressure valve as claimed in claim 9, wherein the component (1) is configured as a nozzle needle or a control valve component of a fuel injector.

11. The process as claimed in claim 4, characterized in that the introduction of the metallic binder material (5) is carried out with a penetration depth (T) of up to 100 nanometers.
